(19) United States
(12) Patent Application Publication
(10) Pub. No.: US 2026/0190633 A1
(43) Pub. Date: Jul. 2, 2026

(54) DISPLAY APPARATUS

(71) Applicant: LG Display Co., Ltd., Seoul (KR)

(72) Inventor: Hee-Jin WON, Paju-si (KR)

(73) Assignee: LG Display Co., Ltd., Seoul (KR)

(21) Appl. No.: 19/198,942

(22) Filed: May 5, 2025

(30) Foreign Application Priority Data
Dec. 30, 2024 (KR) 10-2024-0200601

(51) Int. Cl. H10K 59/122; H10K 59/124; H10K 59/40

(52) U.S. Cl. CPC H10K 59/122; H10K 59/124; H10K 59/40

(57) ABSTRACT

A display apparatus according to the present disclosure comprising a substrate including a display area having a plurality of sub-pixels, each of which has light emitting device, and a non-display area disposed outside the display areal, at least one insulating layer over the substrate, a first planarization layer on the insulating layer, a touch sensor disposed in display area, a first link line disposed on the first planarization layer in the non-display area to apply a signal to the touch sensor, and a bank layer disposed in the display area to divide the sub-pixels, the bank layer being disposed in a part of non-display area, wherein a first step unit is formed in the insulating layer and a second step unit is formed in the first planarization layer, and wherein the bank layer covers the first step unit and the second step unit.

### CROSS-REFERENCE TO RELATED APPLICATIONS

This application claims priority to Korean Patent Application No. 10-2024-0200601, filed in the Republic of Korea on Dec. 30, 2024, the entire contents of which are hereby expressly incorporated by reference into the present application.

### BACKGROUND

### Technical Field

The present disclosure relates to a display apparatus, and more particularly, to the display apparatus capable of preventing touch defects due to cracks in touch line.

### Description of the Related Art

A touch panel is a type of input device that is installed in various display apparatus such as a liquid crystal display apparatus (LCD), an organic light emitting display apparatus (OLED), and an electrophoretic display apparatus (EPD) to input information by directly touching the screen with a finger or a pen while looking at the display apparatus.

The touch panel includes an add-on type that is attached externally separately from the display panel and an in-cell type that is built into the inside of the display panel. Recently, demand for in-cell display panel using the in-cell type is increasing in order to make portable terminals such as smartphones, tablet PCs, and notebook computers slimmer.

### BRIEF SUMMARY

The inventors of the present disclosure recognized that, in in-cell display panels, the touch line is formed within the panel itself. As a result, if the touch line is damaged due to external impact, touch functionality may fail to operate properly. Various embodiments described in this disclosure are directed to overcoming such issues, along with other technical challenges associated with conventional designs.

Various embodiments of the present disclosure provide the display apparatus capable of reducing or minimizing a bezel area.

Various embodiments of the present disclosure provide the display apparatus that prevents defects such as cracks caused by steps.

Various embodiments of the present disclosure provide the display apparatus that prevents defects such as cracks caused by bending.

In one embodiment, a display apparatus includes a substrate having a display area with a plurality of sub-pixels, each incorporating a light emitting device, and a non-display area adjacent to the display area. At least one insulating layer is over the substrate, and a first planarization layer is on the insulating layer. A touch sensor is disposed in display area, a first link line is disposed on the first planarization layer in the non-display area to apply a signal to the touch sensor. A bank layer is disposed in the display area to divide the sub-pixels, the bank layer being disposed in a part of non-display area. A first step unit is formed in the insulating layer and a second step unit is formed in the first planarization layer. The bank layer covers the first step unit and the second step unit.

The insulating layer includes at least one layer of a buffer layer, a gate insulating layer, and an interlayer insulating layer

The first link line is made of the same material as a source electrode and a drain electrode.

A second planarization layer is disposed over the first planarization layer, a second link line is disposed on the first planarization layer, and a connection pattern is disposed on the first planarization layer. The second link line is electrically connected to the first link line through a contact unit and the connection pattern is electrically connected to the thin film transistor and the light emitting device.

The second link line is made of the same material as the connection pattern and the second link line is extended to the display area to be connected electrically to the touch sensor.

The substrate is flexible. A part of the non-display area of the substrate can be bent toward back surface of the substrate. A fixing member made of an adhesive resin is disposed in the space between a bent portion of the substrate and the supporting member.

The various embodiments of the present disclosure relate to a flexible display apparatus with an improved structure that prevents cracks in touch lines and insulating layers during bending. It introduces a design where “step units” formed by insulating and planarization layers in the non-display area are at least partially covered by a bank layer. This spatial configuration, combined with distancing the contact unit from the step units, reduces or minimizes curvature and stress concentration in critical regions, especially under bending conditions. As a result, stress-induced defects such as cracks in the first planarization layer and touch wiring are significantly reduced.

Additionally, the display includes a fixing member, such as an adhesive resin, positioned between the bent portion of the substrate and the supporting components. This configuration helps the bending area maintain a tight curvature while preventing the formation of air gaps and reducing mechanical strain, thereby enhancing overall mechanical durability.

### BRIEF DESCRIPTION OF THE SEVERAL VIEWS OF THE DRAWINGS

FIG. 1 is a schematic block diagram of a display apparatus according to the present disclosure.

FIG. 2 is a schematic block diagram of a sub-pixel of the display apparatus according to the present disclosure.

FIG. 3 is the circuit diagram conceptually showing the sub-pixel of the display apparatus according to the present disclosure.

FIG. 4 is a plan view of the display apparatus according to the present disclosure.

FIG. 5 is a partial sectional view of the display apparatus according to the present disclosure.

FIG. 6 is a partial enlarged plan view of area A of FIG. 4.

FIG. 7 is the cross-sectional view taken along line I-I′ of FIG. 6.

FIG. 8 is the cross-sectional view of a portion of the display apparatus in which a contact portion is formed adjacent to a first step portion and a bank layer does not cover the first step portion and a second step portion.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “coupled,” “in contact” should be interpreted in the same manner.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc., may be used. These terms are only for distinguishing the elements from other elements, and the essence, order, or number of the elements are not limited by the terms. When it is described that a component is “coupled” or “connected” to another component, the component may be directly coupled or connected to the other component, but indirectly without specifically stated. It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the disclosure will be described in detail with reference to the accompanying drawings.

This disclosure can be applied to the various display apparatus. For example, the display apparatus of this disclosure can be applied to various display apparatus such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, the organic light emitting display apparatus will be described as an example for convenience of explanation.

Hereinafter, the present disclosure will be described in detail with reference to the attached drawings.

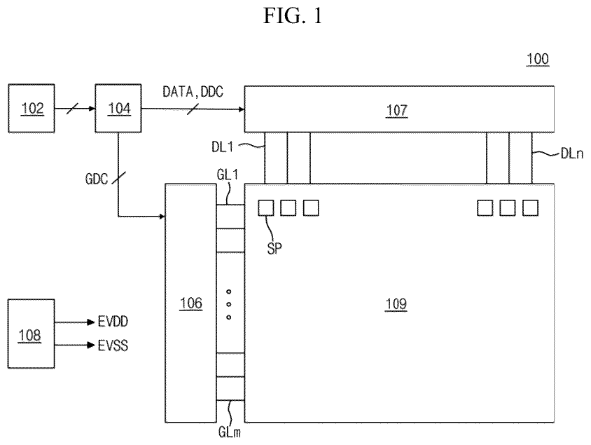

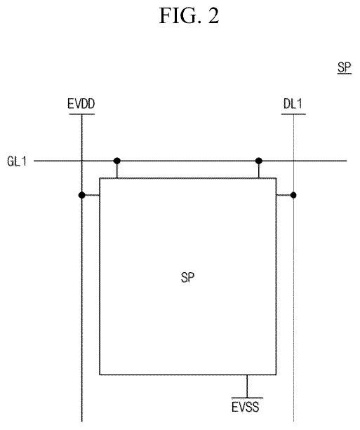

FIG. 1 is the schematic block diagram and FIG. 2 is the schematic block diagram of the sub-pixel of the organic light emitting display apparatus according to this disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is limited thereto.

The power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gage driving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The number of transistors and capacitors as well as the driving method of the sub-pixel (SP) is determined depending on the configuration of the pixel circuit.

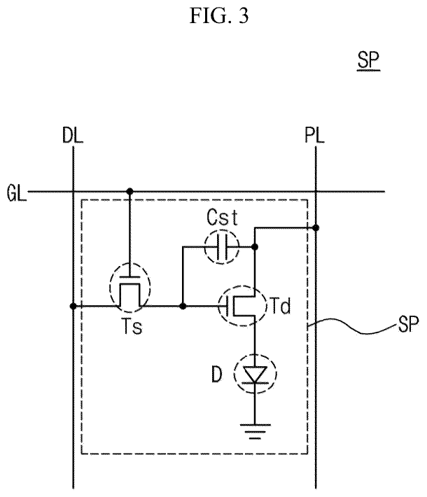

FIG. 3 is the circuit diagram illustrating the sub-pixel SP of the organic light emitting display apparatus 100 according to the present disclosure.

As shown in FIG. 3, the organic light emitting display apparatus 100 according to the present disclosure includes the gate line GL, the data line DL, and the power line PL crossing each other for defining the sub-pixel SP. A switching thin film transistor Ts, a driving thin film transistor DT, a storage capacitor Cst, and a light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the light emitting device D from the power line PL through the driving thin film transistor Td and then the light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

Hereinafter, the display apparatus according to an embodiment of the present disclosure will be specifically described with reference to the attached drawings.

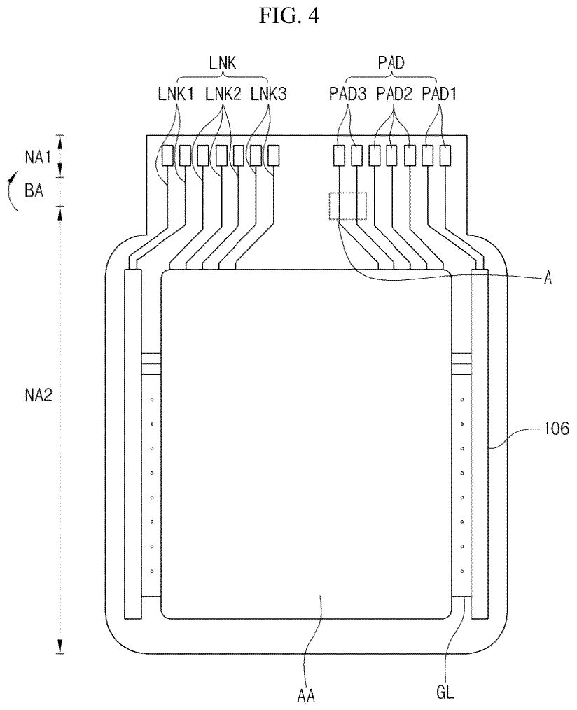

FIG. 4 is the plan of the display apparatus 100 according to the present disclosure.

As shown in FIG. 4, the display apparatus 100 according to the present disclosure includes a display area AA for displaying an image and a non-display area NA disposed outside the display area AA.

The display apparatus 100 may be a flexible display apparatus. At this time, the substrate of the display apparatus 100 is a flexible substrate, and is a base member made of an insulating material to support various components of the display apparatus 100. For example, the substrate may be made of a flexible plastic material such as polyimide (PI).

The display apparatus 100 may have a deformity corner area, and the display area AA may have a shape corresponding to the deformity corner area. For example, the corners of the display area AA and the non-display area NA may be formed in a round shape. However, the display apparatus 100 of the present disclosure is not limited to this shape, and may be formed in various shapes depending on the design of the electronic apparatus to which it is mounted.

The display area AA is a area that the image is displayed. A plurality of pixels P are arranged in the display area AA, and each pixel P includes a plurality of sub-pixels SP. At this time, each of the sub-pixel SP may be a red (R) sub-pixel, a green (G) sub-pixel, or a blue (B) sub-pixel. Further, the sub-pixel SP may be a white (W) sub-pixel.

Although not shown in the figure, a plurality of gate lines and data lines are arranged in the display area AA, and the sub-pixel SP is disposed in the intersection area of the gate line and data line. In each sub-pixel SP, a thin film transistor that is a switching element and a display device to display the image are disposed.

The display apparatus may include various display devices. For example, the display apparatus may be an organic light emitting display device, a liquid crystal display apparatus, a quantum dot display apparatus, a micro LED display apparatus, or a mini LED display apparatus.

The non-display area NA is the area where no image is displayed, and various lines and circuits for driving the display device of the display area AA are arranged. For example, a gate driving unit 106, a data driving unit, link lines LNK, a plurality of pads PAD, etc., may be arranged in the non-display area NA. The non-display area NA may be a bezel area, and this is not limited thereto in the embodiments of the present disclosure.

The non-display area NA includes a first non-display area NA1, a bending area BA, and a second non-display area NA2. The second non-display area NA2 is an area extending from the display area AA. The bending area BA is an area extending from the second non-display area NA2 and can be bent in the direction of an arrow illustrated in FIG. 1. The first non-display area NA1 is an area extending from the bending area BA.

The gate driving unit 106 and a plurality of pads PAD, etc., can be disposed in the first non-display area NA1. The plurality of pads PAD include the pads connected to various link lines LNK and flexible films or printed circuit boards.

The pad PAD includes a plurality of first pads PAD1, a plurality of second pads PAD2, and a plurality of third pads PAD3. The plurality of first pads PAD1 are arranged in both sides of the first non-display area NA1, and the plurality of second pads PAD2 and third pads PAD3 are arranged in the center of the first non-display area NA1. For example, the plurality of second pads PAD2 may be arranged between the plurality of first pads PAD1, and the plurality of third pads PAD3 may be arranged between the plurality of second pads PAD2.

The link line LNK includes a plurality of first link lines LNK1, a plurality of second link lines LNK2, and a plurality of third link lines LNK3.

Each of the plurality of first pads PAD1 is electrically connected to each of the plurality of first link lines LNK1. The plurality of first link lines LNK1 may be link lines connected to the gate driving unit 106.

Each of the plurality of second pads PAD2 is electrically connected to each of the plurality of second link lines LNK2. The plurality of second link lines LNK2 may be link lines connected to data lines, the power lines, etc., arranged in the display area AA.

Each of the plurality of third pads PAD3 are electrically connected to each of the plurality of third link lines LNK1. The plurality of third link lines LNK3 may be touch link lines connected to touch lines.

The gate driving unit 106 supplies a plurality of scan signals to the plurality of gate lines GL according to a plurality of gate control signals provided from the timing control unit. In FIG. 1, only one gate driving unit 106 is disposed spaced apart from one side of the second non-display area NA2, but the number and arrangement of the gate driving unit 106 are not limited thereto.

The second non-display area NA2 is the area surrounding the bending area BA and the display area AA. A plurality of link lines LNK such as a gate link line, a power link line, a data link line, and a touch link line can be disposed in the second non-display area NA2. In other words, the second non-display area NA2 has the function of transmitting signals transmitted from the plurality of pads PAD to the display area AA.

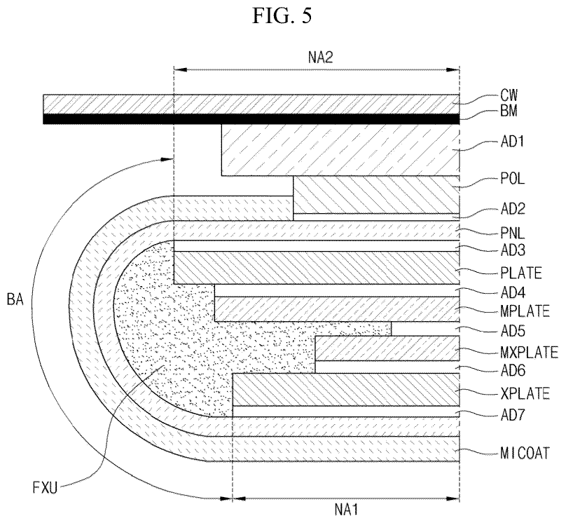

FIG. 5 is a partial cross-sectional view of the display apparatus 100 according to the present disclosure, and is a drawing showing a bending state of the display apparatus 100.

As shown in FIG. 5, a cover window CW is disposed in the front of the display panel PNL. The cover window CW can protect the display panel PNL from external impact and scratches. Further, the cover window CW can protect the display apparatus (or display panel) from moisture or the like penetrating from the outside. The cover window CW may be made of glass or a flexible plastic material, but is not limited thereto.

A black matrix BM is disposed under the cover window CW. The black matrix BM can be disposed along the perimeter of the cover window CW in the outside of the cover window CW. At this time, the area where the black matrix BM is disposed can correspond to the second non-display area NA2. The black matrix BM is formed of a material having low permeability and can prevent various components disposed under the second non-display area (NA2) from being seen to the outside. Further, the black matrix BM is formed of a conductive material to discharge static electricity of the cover window CW.

The black matrix BM can be made of a resin including chromium (Cr), graphite, or conductive particles. The resin can include one or more of an acrylic resin, an epoxy resin, a phenolic resin, a polyamides resin, a polyimides resin, an unsaturated polyesters resin, a polyphenylene resin, a polyphenylene sulfides resin, and benzocyclobutene, but is not limited thereto. Further, the conductive particles can include molybdenum (Mo), chromium (Cr), titanium (Ti), nickel (Ni), neodymium (Nd), copper (Cu), and an alloy of silver (Ag) and magnesium (Mg), but is not limited thereto.

A polarizing plate POL is disposed between the display panel PNL and the cover window CW. The polarizing plate POL is disposed in the front of the display panel PNL. The polarizing plate POL selectively transmits the light to reducing the reflection of external light incident into the display panel PNL.

In general, various metal materials used for the semiconductor device, various types of signal lines, the display device, etc., may be disposed in the display panel PNL. Therefore, the external light incident into the display panel PNL may be reflected from the metal material, and the visibility of the display apparatus 100 may be reduced due to the reflection of the external light. On the other hand, when the polarizing plate POL is disposed, the reflection of external light can be prevented, thereby improving the outdoor visibility of the display apparatus 100. However, the polarizing plate POL may be omitted depending on the type of the display apparatus 100.

A first adhesive layer AD1 is disposed between the polarizing plate POL and the cover window CW to bond the polarizing plate POL and the cover window CW, and a second adhesive layer AD2 is disposed between the polarizing plate POL and a display panel PNL to bond the polarizing plate POL and the display panel PNL. Accordingly, the display panel PNL and the cover window CW are bonded by the first adhesive layer AD1 and the second adhesive layer AD2. The first adhesive layer AD1 and the second adhesive layer AD2 may be formed of a transparent adhesive layer through which an image can be transmitted. For example, the first adhesive layer AD1 and the second adhesive layer AD2 may be formed of an OCA (Optical Clear Adhesive), but are not limited thereto.

The back plate PLATE is disposed under the display panel PNL to support the display panel PNL. For example, if the display panel PNL includes a plastic substrate such as polyimide, a separate component may be required to protect the plastic substrate due to its flexible characteristics. Therefore, the manufacturing process of the display apparatus 100 is performed while the support substrate made of glass is disposed under the display panel PNL, and then the support substrate can be separated after the manufacturing process is completed. However, since the display panel PNL must be supported even after the support substrate is separated, the back plate PLATE is disposed under display panel PNL. The back plate PLATE may be a support member.

The back plate PLATE may include a plastic material. For example, the back plate PLATE may be formed of a plastic film formed of polyimide (PI), polyethylene naphthalate (PEN), polyethylene terephthalate (PET), or a combination of these polymers.

A third adhesive layer AD3 is disposed between the display panel PNL and the back plate PLATE to bond the display panel PNL and the back plate PLATE. The third adhesive layer AD3 may be made of PSA (Pressure Sensitive Adhesive), but is not limited thereto.

A metal plate MPLATE is disposed under the back plate PLATE. The metal plate MPLATE can protect components of the display apparatus 100 from the external impact. Further, the metal plate MPLATE acts as a ground to block the static electricity into the display apparatus 100 or to discharge easily residual charges accumulated within the display apparatus 100 to the outside. In addition, the metal plate MPLATE can easily dissipate heat generated in the display apparatus 100 to the outside.

The metal plate MPLATE can be formed of the metal material having excellent thermal conductivity, electrical conductivity, and mechanical strength. For example, the metal plate MPLATE can be formed of copper (Cu) or stainless steel (SUS), but is not limited thereto.

A fourth adhesive layer AD4 is disposed between the back plate PLATE and the metal plate MPLATE to bond the back plate PLATE and the metal plate MPLATE. The fourth adhesive layer AD4 may be made of PSA Pressure Sensitive Adhesive, but is not limited thereto.

An additional back plate XPLATE and an additional metal plate MXPLATE are disposed under a portion of the metal plate MPLATE corresponding to the first non-display area NA1.

The additional back plate XPLATE and the additional metal plate MXPLATE can supplement the rigidity of the first non-display area NA1 of the display panel PNL. Meanwhile, the additional back plate XPLATE and the additional metal plate MXPLATE can be disposed so as not to overlap with the bending area BA. Accordingly, the thickness of the components disposed in the bending area BA can be minimized, and the neutral plane control of the bending area BA can be facilitated, thereby securing the flexibility of the bending area BA.

A fifth adhesive layer AD5 is disposed between the metal plate MPLATE and the additional metal plate MXPLATE to bond the metal plate MPLATE and the additional metal plate MXPLATE. A sixth adhesive layer AD6 is disposed between the additional metal plate MXPLATE and the additional back plate XPLATE to bond the additional metal plate MXPLATE and the additional back plate XPLATE. For example, the fifth adhesive layer AD5 and the sixth adhesive layer AD6 may be made of a pressure sensitive adhesive (PSA), but are not limited thereto.

The first non-display area NA1 of the display panel PNL is disposed under the additional back plate XPLATE. Further, a seventh adhesive layer AD7 is disposed between the additional back plate XPLATE and the first non-display area NA1 of the display panel PNL to bond the additional back plate XPLATE and the first non-display area NA1 of the display panel PNL. The seventh adhesive layer AD7 may be made of the pressure sensitive adhesive PSA, but is not limited thereto.

A micro-coating layer MICOAT is disposed on the first non-display area NA1, the second non-display area NA2, and the bending area BA of the display panel PNL. The micro-coating layer MICOAT is coated with a thin thickness to protect the link lone to prevent micro-cracks due to tensile force applied to the link line LNK during bending. The micro*coating layer MICOAT may be formed of the acrylic material or the resin such as urethane acrylate, but is not limited thereto.

A fixing member FXU is disposed between both sides of the back plate PLATE, the metal plate MPLATE, the additional metal plate MXPLATE, and the additional back plate XPLATE on the back surface of a display panel (PNL) and the bending area BA that bends to the back surface of the display panel PNL. The fixing member FXU attaches both sides of the back plate PLATE, the metal plate MPLATE, the additional metal plate MXPLATE, and the additional back plate XPLATE to the bending area BA of the display panel PNL to fix the bending area BA. The fixing member FXU may be formed of the adhesive resin. For example, the fixing member FXU may be formed of the epoxy resin, but is not limited thereto.

When the bending area BA of the display panel PNL is bent toward the back surface of the display panel PNL, the stress is applied to the bending area BA. If there is no fixing member FXU, an air layer is formed between both sides of the back plate PLATE, the metal plate MPLATE, the additional metal plate MXPLATE, and the additional back plate XPLATE and the bending area BA of the display panel PNL. Therefore, in order to minimize the stress in the bending area BA, the curvature of the bending area BA must be minimized, and as a result, the bezel area of the display apparatus 100 is increased.

On the other hand, when a fixed member FXU is disposed, the bending area BA can be fixed by the adhesive force of the fixed member FXU, so that the curvature of the bending area BA can be maximized, and as a result, the bezel area of the display apparatus 100 can be decreased

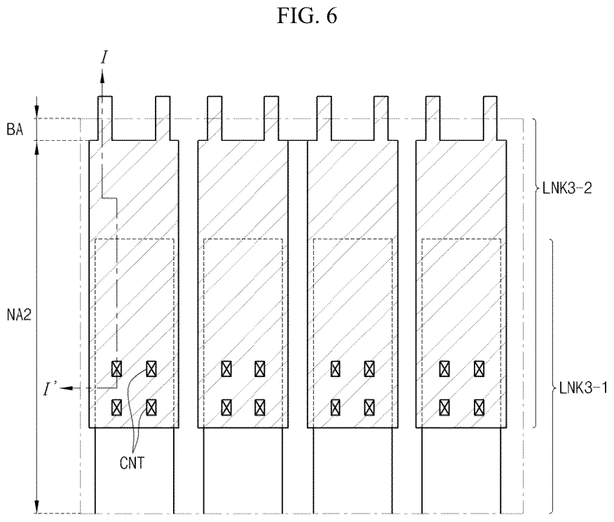

FIG. 6 is a partial enlarged plan view of area A of FIG. 4.

As shown in FIG. 6, the display panel PNL of the display apparatus 100 includes the display area AA and the non-display area NA. The non-display area NA includes the first non-display area NA1, the second non-display area NA2, and the bending area BA.

A plurality of third link lines LNK3 are disposed in the first non-display area NA1, the second non-display area NA2, and the bending area BA. The third link lines LNK3 apply a touch signal to the display panel PNL.

The third link line LNK3 includes a plurality of third-first link lines LNK3-1 and a plurality of third-second link lines LNK3-2. The plurality of third-first link lines LNK3-1 can be disposed in the non-display area NA and the bending area BA, and the plurality of third-second link lines LNK3-2 can be disposed in the non-display area NA.

A plurality of contact holes CNT are formed in the second non-display area NA2. As will be described later, the third-first link line LNK3-1 and the third-second link line LNK3-2 are formed in different layers with an insulating layer therebetween, and the third-first link line LNK3-1 and the third-second link line LNK3-2 are electrically connected through the contact holes CNT.

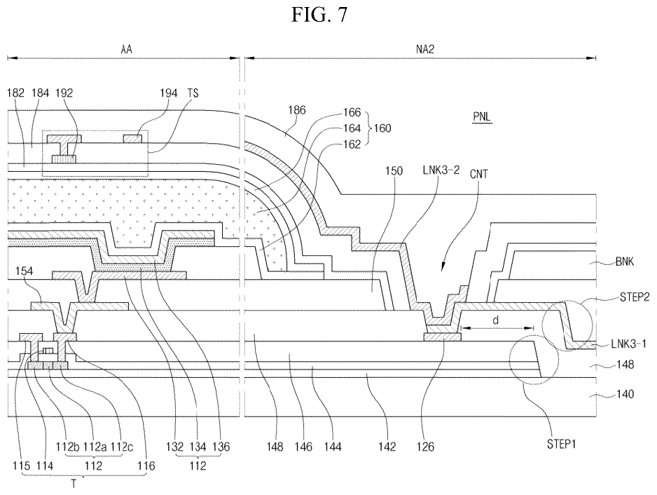

FIG. 7 is a cross-sectional view taken along line I-I′ of FIG. 6, which specifically illustrates the structure of the display panel PNL of the display apparatus 100 of the present disclosure. In the drawing, only the display area AA and the non-display area NA are illustrated for convenience of explanation, and in particular, one sub-pixel of the display area AA and the second non-display area NA2 are illustrated.

As shown in FIG. 7, the substrate 140 includes the display area (AA) and the second non-display area NA2.

The substrate 140 may be made of a plastic material, but not limited thereto. For example, the plastic material may include at least one of a polyimide, a polymethylmethacrylate, a polyethylene tereththalate, a Polyethersulfone, and a Polycarbonate, but not limited thereto

When the substrate 140 is made of polyimide, the substrate 140 may be made of a plurality of polyimide layers, and an inorganic layer may be further disposed between the polyimide layers, but is not limited thereto. If the inorganic layer is further disposed between the polyimides, the inorganic layer may not be formed in a part of the second non-display area NA2. For example, the inorganic layer may be patterned in at least a part of the second non-display area NA2.

A buffer layer 142 is formed on the substrate 140. The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor is formed on the buffer layer 142 in the display area AA. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the buffer layer 142, a gate insulating layer 144 covering the semiconductor pattern 112, a gate electrode 113 on the gate insulating layer 144, an interlayer insulating layer 146 covering the gate electrode 113, and a source electrode 114 and a drain electrode 115 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

The gate insulating layer 144 may be composed of a single layer or multiple layers made of an inorganic material such as SiOx or SiNx, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A first planarization layer 148 is formed on the substrate where the thin film transistor is disposed. The first planarization layer 148 may be formed of the organic material such as photoacrylic, but it is not limited thereto. The first planarization layer 148 may include a plurality of layers including the inorganic layer and the organic layer.

A connection pattern 154 is disposed on the first planarization layer 148 and is electrically connected to the drain electrode 116 of the thin film transistor T through a contact hole formed in the first planarization layer 148. The connection pattern 154 may be made of metal.

A second planarization layer 150 is formed on the first planarization layer 148 on which a connection pattern 154 is formed. The second planarization layer 150 may be formed of the organic material such as photoacrylic, but it is not limited thereto. The second planarization layer 150 may include a plurality of layers including the inorganic layer and the organic layer. The second planarization layer 150 may include a plurality of layers including the inorganic layer and the organic layer.

In the present disclosure, by forming the planarization layer in a two-layer structure 148 and 150, various electrodes and signal lines can be formed between the first and second planarization layers 148 and 150. Accordingly, since the electrodes can be arranged vertically, the area due to the electrodes and signal line in the sub-pixel can be reduced, and as a result the area of the sub-pixel can be reduced for a high-resolution display apparatus 100.

A light emitting device D is disposed on the second planarization layer 158. The light emitting device D includes a first electrode 132, an organic layer 134, and a second electrode 136.

The first electrode 132 is disposed on the second planarization layer 150 and electrically connected to the drain electrode 115 of the thin film transistor through the contact hole formed in the second planarization layer 148. The first electrode 132 may be formed of at least one of silver (Ag), aluminum (Al), gold (Au), molybdenum (Mo), tungsten (W), chromium (Cr), or an alloy thereof.

Further, the first electrode 132 may be formed of a transparent metal oxide material such as indium tin oxide (ITO) or indium zinc oxide (IZO). When the first electrode 132 is made of the transparent metal oxide layer, the first electrode 132 may further include an opaque conductive material to function as a reflective electrode that reflects light.

A bank layer BNK is formed at the boundary between the sub-pixels on the second planarization layer 150. The bank layer 152 may be a barrier wall to define sub-pixels. The bank layer BNK divides each sub-pixel to prevent light of a specific color output from adjacent pixels from being mixed and output.

The bank layer BNK is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

The light emitting layer 134 may be formed in the R, G, and B pixels and may include an R-emitting layer that emits red light, a G-emitting layer that emits green light, and a B-emitting layer that emits blue light. For example, the light emitting layer 134 may include an organic light emitting layer, an inorganic light emitting layer, a nano-sized material layer, a quantum dot, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the half-transparent conductive material that transmits light. For example, the second electrode 188 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag. Further, the second electrode 136 may be made of a transparent metal oxide such as indium tin oxide (ITO) or indium zinc oxide (IZO), but is not limited thereto.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

Am encapsulation layer 160 is formed on the light emitting device D to seal the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating into the light emitting device D oxidizes the metal electrode. The encapsulation layer 160 blocks impurities such as the oxygen and the moisture from the outside to prevent defects of the light emitting device D and various electrodes.

The encapsulation layer 160 may be formed of a first encapsulation layer 162, a second encapsulation layer 164, and a third encapsulation layer 166, but is not limited thereto. The encapsulation layer 160 may be formed of two layers or four or more layers.

The first encapsulation layer 162 and the third encapsulation layer 166 may be formed of a single layer or multiple layers including the inorganic materials such as SiOx, SiON, SiNx, etc. In this case, the organic material may be further included between the inorganic materials such as SiOx, SiON, SiNx, etc., but is not limited thereto. The second encapsulation layer 164 may be made of an epoxy resin.

A touch buffer layer 182 is formed on the encapsulation layer 160, and a touch sensor TS is disposed on the touch buffer layer 182. The touch sensor TS includes a bridge electrode 192 disposed on the touch buffer layer 182, a touch interlayer insulating layer 184 disposed on the bridge electrode 192, and a touch electrode 194 disposed on the touch interlayer insulating layer 184.

The touch buffer layer 182 and the touch layer inter insulating layer 184 may be made of the inorganic materials. For example, the touch buffer layer 182 and the touch layer inter insulating layer 184 may be made of SiOx or SiNx, but are not limited thereto.

The bridge electrode 192 and the touch electrode 194 may be formed of the single layer or the multiple layers made of one or an alloy of molybdenum (Mo), aluminum (Al), chromium (Cr), gold (Au), titanium (Ti), nickel (Ni), neodymium (Nd), and copper (Cu). Further, the bridge electrode 192 and the touch electrode 194 may be made of the transparent metal oxide such as ITO or IZO.

The bridge electrode 192 and the touch electrode 194 are electrically connected through the contact hole formed in the touch interlayer insulating layer 184. Although not shown in the drawing, the touch electrode 194 may be formed in a mesh shape.

A touch planarization layer 186 is formed on the touch sensor TS to protect the touch sensor TS. The touch planarization layer 186 may be made of the organic material, or may be formed of the multiple layers of organic layers and inorganic layers.

In the drawing, the touch sensor TS is disposed on the encapsulating layer 160, but the present disclosure is not limited to this structure. The touch sensor TS can be disposed under the encapsulating layer 160.

A contact electrode 126 is formed on the interlayer insulating layer 146 of the second non-display area NA2, and a contact structure CNT (also referred to as “contact unit CNT”) is formed by removing the first planarization layer 148 above the contact electrode 126. A part of the contact electrode 126 is exposed to the outside through the contact unit CNT. The contact unit CNT may be the contact hole formed in the interlayer insulating layer 146, but is not limited thereto.

The third-first link line LNK3-1 is disposed on the first planarization layer 148 in the second non-display area NA2. The third-first link line LNK3-1 is extended within the contact unit CNT so that the third-first link line LNK3-1 is electrically connected to the contact electrode 126.

The third-second link line LNK3-1 is disposed on the second planarization layer 150. The third-second link line LNK3-2 is extended to the display area AA and is electrically connected to the touch electrode 194 of the touch sensor TS. At this time, the third-second link line LNK3-1 is formed on the upper surface of the touch interlayer insulating layer 184 and extends to the touch sensor TS in the display area AA.

The third-first link line LNK3-1 and the third-second link line LNK3-2 may be touch lines that applies the touch signal to the touch sensor TS.

The third-second link line LNK3-2 is extended into the contact unit CNT and is electrically connected to the third-first link line LNK3-1. That is, the third-first link line LNK3-1 and the third-second link line LNK3-2 are electrically connected by the contact unit CNT to supply the external touch signal to the touch sensor TS and output a detection signal detected by the touch sensor TS to the outside. The third-first link line LNK3-1 may be made of the same metal as the source electrode 115 and the drain electrode 116 of the thin film transistor T, but is not limited thereto.

A first step structure STEP1 (also referred to as “a first step unit STEP1”) is formed in the outside of the contact unit CNT in the non-display area NA by the buffer layer 142, the gate insulating layer 144, and the interlayer insulating layer 146. The first step unit STEP1 is formed at a predetermined distance (d) from the contact unit CNT. In the drawing, the first step unit STEP1 is formed by the buffer layer 142, the gate insulating layer 144, and the interlayer insulating layer 146, but may be formed by at least one layer of the buffer layer 142, the gate insulating layer 144, and the interlayer insulating layer 146. A second step structure STEP2 (also referred to as “a second step unit STEP2”) is formed in the first planarization layer 148 by the first step unit STEP1.

The bank layer BNK is disposed on the second planarization layer 150 in the second non-display area NA2. At this time, the bank layer BNK is spaced apart from the contact unit CNT by a certain distance to cover completely the first step unit STEP1 and the second step unit STEP2.

As described above, in the present disclosure, the contact unit CNT is spaced apart from the first step unit STEP1 by a certain distance (d) and the bank layer BNK completely covers the first step unit STEP1 and the second step unit STEP2, for the following reasons.

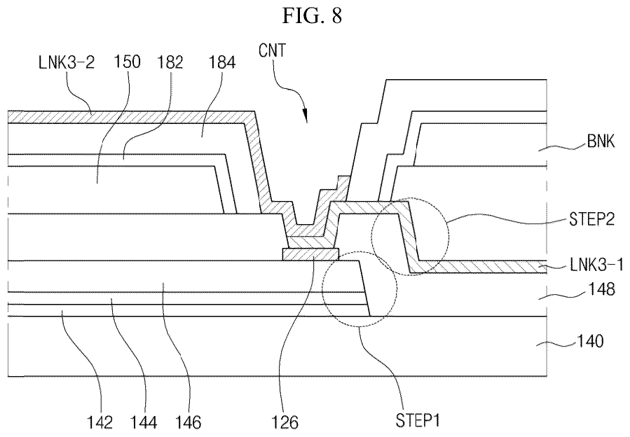

FIG. 8 is the drawing showing the structure in which the contact unit CNT is formed adjacent to the first step unit STEP1 and the bank layer BNK does not cover the first step unit STEP1 and the second step unit STEP2.

As shown in FIG. 8, in the display apparatus of this structure, since the contact unit CNT is formed adjacent to the first step unit STEP1, many curvatures are formed in the first planarization layer 148 in this region due to the steps of the contact unit CNT and the second step unit STEP2. Accordingly, when the second non-display area NA2 is bent, a strong stress is applied to the first planarization layer 148 in this region. At this time, the first planarization layer 148 may be made of the organic material having property that is strong against external stress.

Further, when the second non-display area NA2 is bent, the stress due to the bending is applied to both of the first planarization layer 148 and the third-first link line LNK3-1 having the steps, so that the strong stress is applied to the first planarization layer 148 and the third-first link line LNK3-1, and as a result, the defects such as cracks are generated in the first planarization layer 148 and the third-first link line LNK3-1. In other words, the first planarization layer 148 may not be surrounded by the first step unit STEP1, and many curvatures may be formed in the first planarization layer 148. Accordingly, the second step unit STEP2 may be formed adjacent to the first step unit STEP1. Further, when the second non-display area NA2 is bent, the strong stress may be applied to the first planarization layer 148 and the third-first link line LNK3-1, and the defects such as cracks may be generated in the first planarization layer 148 and the third-first link line LNK3-1.

However, in the present disclosure, by forming the contact unit CNT to be spaced apart from the first step unit STEP1 by a certain distance (d), the curvature of the first planarization layer 148 near the contact unit CNT and the first step unit STEP1 is minimized, thereby minimizing the stress applied to the first planarization layer 148 in this area.

Further, in the present disclosure, since the bank layer BNK completely covers the first step unit STEP1 and the second step unit STEP2, the bank layer BNK can absorb the stress applied to this area, and as a result, the cracks in the first planarization layer 148 and the third-first link line LNK3-1 due to stress can be prevented.

Further, in the present disclosure, since the first planarization layer 148 covers the first step unit STEP1, the upper surface of the first planarization layer 148 above the first step unit STEP1 is formed flatly. Accordingly, the third-first link line LNK3-1 disposed on the first planarization layer 148 can also be formed flatly without the step.

Meanwhile, in the above-described description, the touch sensor TS is disposed on the encapsulation layer 160 and the third-second link line LNK3-2 is extended to the upper surface of the encapsulation layer 160, but the present disclosure is not limited to this structure. For example, when the touch sensor TS is disposed on the encapsulation layer 160, the third-second link line LNK3-2 is extended to the display area AA under the encapsulation layer 160 to be connected electrically to the touch sensor TS.

As described above, in the display apparatus according to the present disclosure, the space between the bending unit of the display panel and the various plates under the display panel is filled with adhesive resin to attach the bending unit of the display panel and the plates. Accordingly, even if the curvature of the bending unit of the display panel is maximized, the damage due to stress can be prevented, so that the bezel area of the display apparatus can be reduced.

Further, in the present disclosure, since the bank layer covers the steps of insulating layers such as the buffer layer, the gate insulating layer, and the interlayer insulating layer, and the steps of the first planarization layer, even when the curvature of the bending portion of the display panel is maximized, the bank layer absorbs the stress caused by bending of the flexible substrate, thereby preventing cracks in the insulating layer and the touch wiring.

Embodiments according to the present disclosure can be described as follows.

According one embodiment of the present disclosure, a display apparatus can comprises a substrate including a display area having a plurality of sub-pixels, each of which has light emitting device, and a non-display area disposed outside the display area, at least one insulating layer over the substrate, a first planarization layer on the insulating layer, a touch sensor disposed in display area, a first link line disposed on the first planarization layer in the non-display area to apply a signal to the touch sensor, and a bank layer disposed in the display area to divide the sub-pixels, the bank layer being disposed in a part of non-display area, wherein a first step unit is formed in the insulating layer and a second step unit is formed in the first planarization layer, and wherein the bank layer covers the first step unit and the second step unit.

According one embodiment of the present disclosure, the insulating layer can be made of an inorganic material.

According one embodiment of the present disclosure, the insulating layer can include at least one layer of a buffer layer, a gate insulating layer, and an interlayer insulating layer.

According one embodiment of the present disclosure, a thin film transistor can be disposed each of the sub-pixels over the insulating layer, and the thin film transistor can include a semiconductor layer over the insulating layer, a gate electrode over the semiconductor layer, and a source electrode and a drain electrode over the gate electrode.

According one embodiment of the present disclosure, the first link line can be made of the same material as the source electrode and the drain electrode.

According one embodiment of the present disclosure, a second planarization layer can be disposed over the first planarization layer. a second link line can be disposed on the first planarization layer, and a connection pattern can be disposed on the first planarization layer. The second link line can be electrically connected to the first link line through a contact unit and the connection pattern can be electrically connected to the thin film transistor and the light emitting device.

According one embodiment of the present disclosure, the contact unit can be a contact hole formed in first planarization layer

According one embodiment of the present disclosure, the second link line can be made of the same material as the connection pattern.

According one embodiment of the present disclosure, the second link line can be extended to the display area to be connected electrically to the touch sensor.

According one embodiment of the present disclosure, the encapsulation layer can be disposed over the light emitting device.

According one embodiment of the present disclosure, the second link can be extended to the upper surface of the encapsulation layer in the display area.

According one embodiment of the present disclosure, the substrate can be flexible.

According one embodiment of the present disclosure, a part of the non-display area of the substrate can be bent toward back surface of the substrate.

According one embodiment of the present disclosure, at least one supporting member can be disposed in the back surface of the substrate to support the substrate and a fixing member can be disposed in the space between a bent portion of the substrate and the supporting member.

According one embodiment of the present disclosure, the fixing member can include an adhesive resin.

According one embodiment of the present disclosure, the second link line can be overlapped with the first step unit with the first planarization layer and the second planarization layer interposed therebetween, so that the second link line is formed flat on the first planarization layer.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a display area having a plurality of sub-pixels, each of which has light emitting device, and a non-display area adjacent to the display area;
at least one insulating layer on the substrate;
a first planarization layer on the insulating layer;
a touch sensor in display area;
a first link line on the first planarization layer in the non-display area to apply a signal to the touch sensor; and
a bank layer in the display area to divide the sub-pixels, the bank layer being disposed in a part of non-display area,
wherein a first step structure is formed in the insulating layer and a second step structure is formed in the first planarization layer, and
wherein the bank layer covers the first step structure and the second step structure.

2. The display apparatus of claim 1, wherein the insulating layer is made of an inorganic material.

3. The display apparatus of claim 2, wherein the insulating layer includes at least one layer of a buffer layer, a gate insulating layer, and an interlayer insulating layer.

4. The display apparatus of claim 1, further comprising a thin film transistor disposed each of the sub-pixels over the insulating layer,
wherein the thin film transistor includes a semiconductor layer on the insulating layer, a gate electrode on the semiconductor layer, and a source electrode and a drain electrode on the gate electrode.

5. The display apparatus of claim 4, wherein the first link line is made of a same material as the source electrode and the drain electrode.

6. The display apparatus of claim 4, further comprising:
a second planarization layer on the first planarization layer;
a second link line on the first planarization layer; and
a connection pattern on the first planarization layer,
wherein the second link line is electrically connected to the first link line through a contact structure, and
wherein the connection pattern is electrically connected to the thin film transistor and the light emitting device.

7. The display apparatus of claim 6, wherein the contact structure is a contact hole formed in first planarization layer.

8. The display apparatus of claim 6, wherein the second link line is made of the same material as the connection pattern.

9. The display apparatus of claim 6, wherein the second link line is extended to the display area to be connected electrically to the touch sensor.

10. The display apparatus of claim 6, further comprising an encapsulation layer over the light emitting device.

11. The display apparatus of claim 10, wherein the second link line is extended to the upper surface of the encapsulation layer in the display area.

12. The display apparatus of claim 11, wherein the substrate is flexible.

13. The display apparatus of claim 12, wherein a part of the non-display area of the substrate is bent toward back surface of the substrate.

14. The display apparatus of claim 13, further comprising:
at least one supporting member disposed in the back surface of the substrate to support the substrate; and
a fixing member disposed in the space between a bent portion of the substrate and the supporting member.

15. The display apparatus of claim 14, wherein the fixing member includes an adhesive resin.

16. The display apparatus of claim 6, wherein the second link line is overlapped with the first step structure with the first planarization layer and the second planarization layer interposed therebetween, so that the second link line is formed flat on the first planarization layer.
